(19) United States
(12) Patent Application Publication
(10) Pub. No.: US 2015/0251913 A1
(43) Pub. Date: Sep. 10, 2015

(54) GRAPHENE MACHINING METHOD

(71) Applicant: TOKYO ELECTRON LIMITED, Tokyo (JP)

(72) Inventors: Takashi MATSUMOTO, Nirasaki City (JP); Kazuya DOBASHI, Nirasaki City (JP)

(21) Appl. No.: 14/634,948

(22) Filed: Mar. 2, 2015

(30) Foreign Application Priority Data
Mar. 6, 2014 (JP) 2014-043828

(51) Int. Cl. C01B 31/04; H01J 37/305

(52) U.S. Cl. CPC C01B 31/0484; H01J 37/3056; C01B 2204/06; C01B 2204/22

(57) ABSTRACT

A graphene machining method includes irradiating a GCB (Gas Cluster Beam) onto graphene.

### CROSS-REFERENCE TO RELATED APPLICATION

This application claims the benefit of Japanese Patent Application No. 2014-043828, filed on Mar. 6, 2014, in the Japan Patent Office, the disclosure of which is incorporated herein in its entirety by reference.

### TECHNICAL FIELD

The present disclosure relates to a graphene machining method using a gas cluster beam (GCB).

### BACKGROUND

Graphene is an aggregate of six-membered ring structures composed by carbon atoms. Since graphene has a higher-mobility, e.g., a mobility of 200,000 cm²/V·s, than silicon, it has been studied to apply graphene to semiconductor devices such as high-speed switching devices or high-frequency devices. In addition, since graphene is ballistically conductive, it has been also studied to use graphene as a wiring material in semiconductor devices instead of copper (Cu).

Prior to applying graphene to semiconductor devices, it is necessary to machine graphene into a ribbon, e.g., about 10 nm in width (hereinafter referred to as “graphene ribbon”). Both side ends (hereinafter referred to as “edges”) of the machined graphene ribbon shows either armchair edges, which are a part of continuous six-membered ring structures in trans-polyacetylene illustrated in FIG. 8A, or zigzag edges which are a part of continuous six-membered ring structures in cis-polyacetylene illustrated in FIG. 8B.

Electrical properties of a graphene ribbon, e.g., mobility, electrical conductivity or band gap, varies according to the shape of edges thereof. For example, a graphene ribbon having zigzag edges can be appropriately used in wirings because it shows highs mobility or electrical conductivity, and a graphene ribbon having armchair edges can be appropriately used in transistors because it creates a band gap. Therefore, when obtaining a graphene ribbon, it is important to control the edge shape of the graphene ribbon.

Lithography, e.g., reactive ion etching (RIE) using a mask, is used in conventional graphene machining. RIE uses high-energy plasma. Therefore, ions in the plasma may cleave the six-membered ring structures when they collide with the graphene so that the edges of the graphene ribbon may collapse. In order to solve this problem, it has been studied to restore the edges after obtaining a graphene ribbon through graphene machining, by performing anneal processing or plasma processing on the graphene ribbon under a reactive gas atmosphere, for example, hydrogen (H₂) gas atmosphere, oxygen (O₂) gas atmosphere, ammonia (NH₃) gas atmosphere, a hydrocarbon (CₓH_{y}) gas atmosphere or the like, such that functional groups are combined to the cleaved six-membered ring structures. However, it is difficult to completely restore the edges by only combining the functional groups.

Therefore, it has been also studied to apply gas cluster ion beam (GCIB), which uses clusters of relatively low-energy gas molecules, to graphene machining. In particular, the present inventors suggested a method wherein graphene is machined using GCIB of water molecules to selectively obtain chemically-stable armchair edges by a synergy effect with low-oxidizing power of water molecules.

However, in GCIB, gas molecules or clusters of a plurality of gas molecules are ionized, or electric charges are attached to the gas molecules or the clusters. For these reasons, the electric charges may remain in the graphene ribbon machined using GCIB, and it is likely that the remaining electric charges affect electrical characteristics of a semiconductor device to which the graphene ribbon is applied.

### SUMMARY

The present disclosure provides a graphene machining method capable of preventing graphene edges from collapsing while preventing electric charges from remaining in a graphene ribbon.

According to an embodiment of the present disclosure, there is provided a graphene machining method including irradiating a GCB (Gas Cluster Beam) onto graphene.

### BRIEF DESCRIPTION OF THE DRAWINGS

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. Throughout the drawings, the elements are denoted by the same reference numerals.

FIG. 1 is a vertical sectional view schematically illustrating a configuration of a GCB irradiation device which performs a graphene machining method according to an embodiment of the present disclosure.

FIG. 2 is a horizontal sectional view of the GCB irradiation device of FIG. 1.

FIG. 3 is a vertical sectional view schematically illustrating a configuration of a GCB irradiation nozzle illustrated in FIG. 1.

FIG. 4 illustrates GCB irradiation to graphene.

FIG. 5 is a partial plan view illustrating a wafer in which graphene is partially removed by the GCB irradiation.

FIG. 6 is a graph illustrating a surface property of the wafer, which has a graphene removed portion as illustrated in FIG. 5, wherein the surface property is analyzed by Raman spectroscopy.

FIGS. 7A to 7C are process diagrams illustrating the graphene machining method according to the embodiment of the present disclosure.

FIGS. 8A and 8B are partial enlarged plan views illustrating shapes of graphene edges, wherein FIG. 8A shows armchair edges and FIG. 8B shows zigzag edges.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other examples, well-known methods, procedures, systems, and components have not been described in detail so as not to unnecessarily obscure aspects of the various embodiments. Throughout the drawings, the elements are denoted by the same reference numerals.

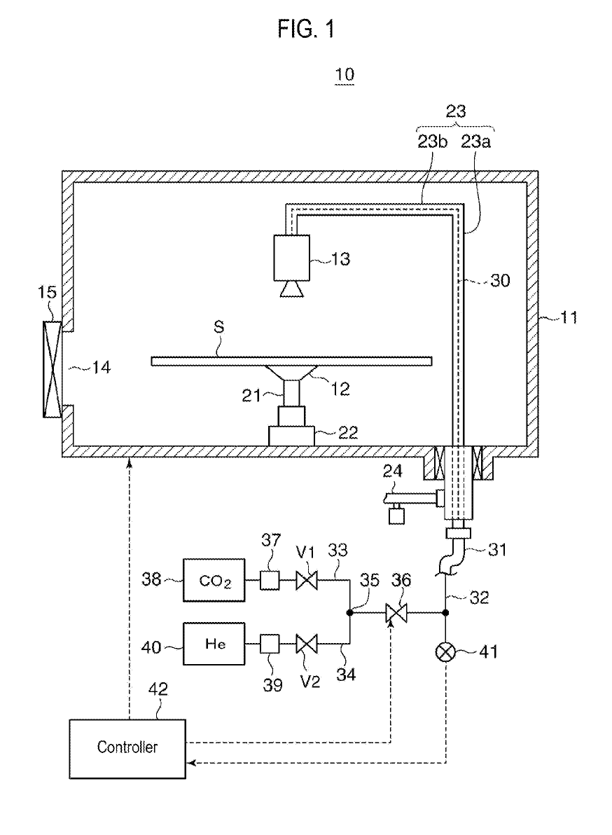

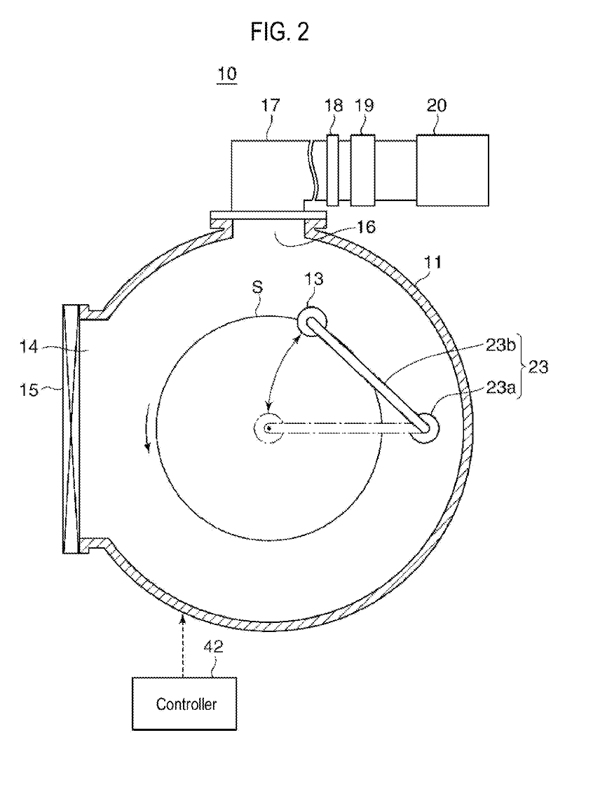

FIG. 1 is a vertical sectional view schematically illustrating a configuration of a GCB irradiation device which performs a graphene machining method according to an embodiment of the present disclosure. FIG. 2 is a horizontal sectional view of the GCB irradiation device of FIG. 1.

In FIGS. 1 and 2, the GCB irradiation device 10 includes a chamber 11 constituted by a cylindrical vacuum container, a rotation stage 12 arranged in a bottom portion of the chamber 11, and a GCB irradiation nozzle 13 arranged within the chamber 11 to face the rotation stage 12. Unlike the conventional etching or GCIB irradiation devices, the GCB irradiation device 10 does not need to have a plasma generation mechanism or electron beam ionization unit.

A loading/unloading gate 14 for loading/unloading a substrate S having a front surface where the graphene is formed is arranged in a portion of a side surface of the chamber 11. A gate valve 15 for opening/closing the loading/unloading gate 14 is installed in the loading/unloading gate 14.

An exhaust port 16 is arranged in another portion of the side surface of the chamber 11, and an exhaust passage 17 is connected to the exhaust port 16. The exhaust passage 17 is connected to a vacuum pump 20 constituted by, e.g., a turbo molecule pump, through a pressure adjustment valve 18 and an opening/closing valve 19. The vacuum pump 20 depressurizes the inside of the chamber 11 through the exhaust passage 17, and the pressure adjustment valve 18 sets the internal pressure of the chamber 11 to be a desired vacuum level, e.g., 10⁻⁴ Pa.

The rotation stage 12 holds the substrate S, and is connected to a driving part 22 via a rotation axis 21. The driving part 22 applies a rotation driving force to the rotation axis 21. The rotation stage 12 is configured to rotate around the rotation axis 21 or move in a vertical direction in the figures by the driving part 22. The rotation stage 12 adsorbs the substrate S through an electrostatic chuck mechanism or a vacuum adsorption mechanism (both not shown).

The GCB irradiation nozzle 13 is held by a nozzle moving part 23 that includes a revolving axis 23a installed beside the rotation stage 12 and a revolving arm 23b extending from the upper end of the revolving axis 23a in a direction toward the rotation stage 12. The revolving axis 23a penetrates the bottom portion of the chamber 11 and is engaged with a rotary mechanism 24 outside of the chamber 11. The rotary mechanism 24 rotates the revolving axis 23a so that the GCB irradiation nozzle 13 makes revolving movement around the revolving axis 23a. As a result, the GCB irradiation nozzle 13 advances toward and retreats from above the substrate S held on the rotation stage 12.

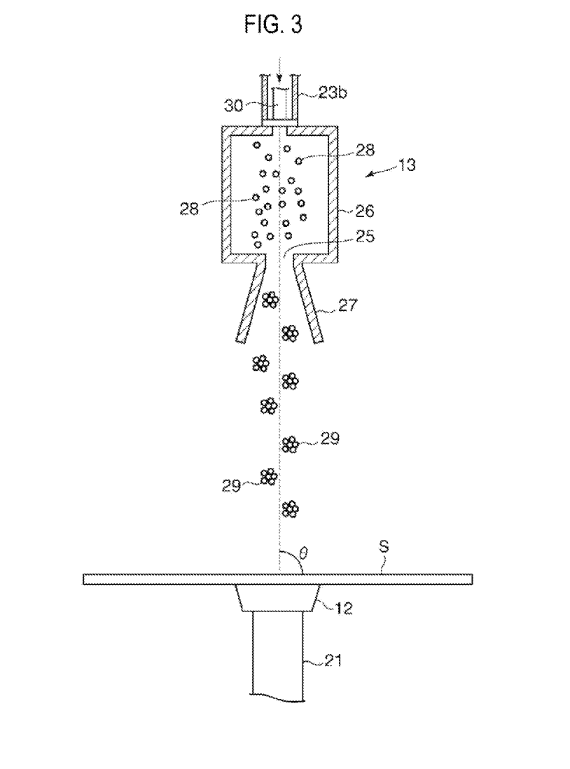

FIG. 3 is a vertical sectional view schematically illustrating a configuration of the GCB irradiation nozzle illustrated in FIG. 1.

In FIG. 3, the GCB irradiation nozzle 13 includes a substantially cylindrical pressure vessel 26 having an open lower end portion to form an orifice 25, and a cone-shaped gas diffusion part 27 having a downwardly increasing diameter. The gas diffusion part 27 is formed in the lower end of the pressure vessel 26 and communicates with the inside of the pressure vessel 26 through the orifice 25. The opening diameter of the orifice 25 is, e.g., 0.1 mm.

The GCB irradiation nozzle 13 discharges gas molecules 28 from the pressure vessel 26, which has an inner pressure higher than that of the chamber 11, toward the substrate S. That is to say, the gas molecules 28 are introduced into the chamber 11. At this time, since the diameter of the gas diffusion part 27 is downwardly increasing, the discharged gas molecules 28 are rapidly cooled by adiabatic expansion, which decreases kinetic energy of the respective gas molecules 28. Accordingly, the gas molecules 28 make close contact with each other by an intermolecular force applied among the gas molecules 28, i.e., by the van der Walls force. As a result, a plurality of gas clusters 29 made of two or more gas molecules 28 is formed. The formed gas clusters 29 directly move toward the substrate S and collide with the substrate S. In other words, a GCB made of a plurality of gas clusters 29 is irradiated onto the substrate S.

In the GCB irradiation nozzle 13, the form of the gas clusters 29 depends on the opening diameter of the orifice 25 or the shape of the gas diffusion part 27. Since the gas clusters 29 may be decomposed if the temperature increases, the pressure vessel 26 may be cooled down when irradiating the gas clusters 29.

The GCB irradiation nozzle 13 is configured to vertically irradiate the GCB onto the surface of the substrate S. In this embodiment, “vertical” means a state that an angle θ between the substrate S and the center axis of the pressure vessel 26 is in a range of 90°±15° in the drawing.

In the GCB irradiation nozzle 13, a pipe 30 is connected to the upper end portion of the pressure vessel 26. As illustrated in FIG. 2, the pipe 30 penetrates the inside of the revolving arm 23b and the revolving axis 23a, and is connected to a gas supply passage 32 through a connector 31 outside of the chamber 11. The gas supply passage 32 branches at a branch point 35 into a first gas supply passage 33 and a second gas supply passage 34. A pressure adjustment valve 36 is arranged between the connector 31 and the branch point 35.

A carbon dioxide (CO₂) gas supply source 38 is connected to the first gas supply passage 33 through an opening/closing valve V1 and a flow rate controller 37. A helium (He) gas supply source 40 is connected to the second gas supply passage 34 through an opening/closing valve V2 and a flow rate controller 39.

A pressure detector 41 is arranged in the gas supply passage 32. Based on a detection value of the pressure detector 41, the opening degree of the pressure adjustment valve 36 is controlled by a controller 42 to be described later, and thus the internal pressure of the pressure vessel 26 of the GCB irradiation nozzle 13 is controlled. Instead of installing the pressure detector 41 in the gas supply passage 32, a pressure detector may be installed in the pressure vessel 26 so that the internal pressure of the pressure vessel 26 may be controlled based on a detection value of the pressure detector.

In the GCB irradiation device 10, a GCB is irradiated onto the entire surface of the substrate S by the revolving movement of the GCB irradiation nozzle 13 and the rotation of the rotation stage 12. The revolving movement of the GCB irradiation nozzle 13, the rotation of the rotation stage 12 or the like in the GCB irradiation device 10 is controlled by the controller 42 included in the GCB irradiation device 10. The controller 42 is configured by, for example, a computer, and has a memory for storing programs, a RAM as a program expansion area and a CPU. The CPU executes the programs expanded in the RAM, whereby the graphene machining method according to the present embodiment is performed.

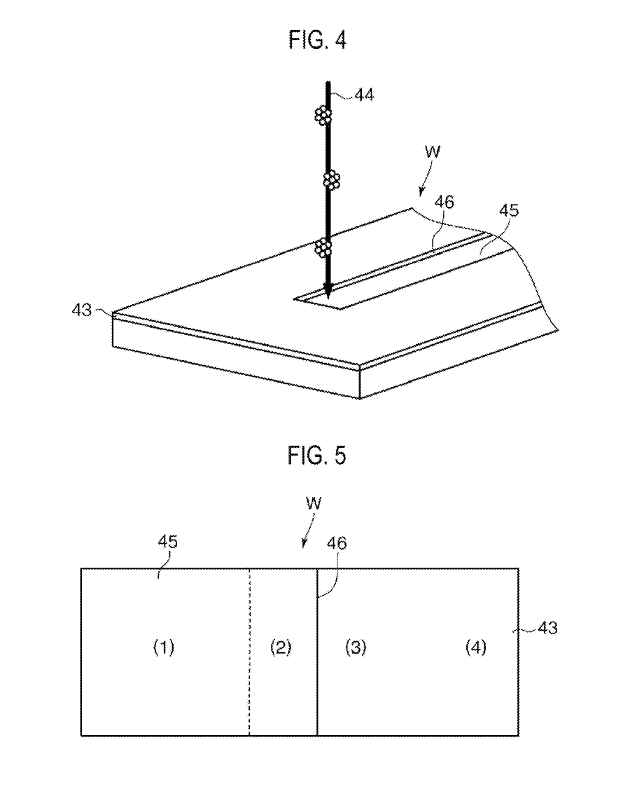

Hereinafter, experimental results will be described according to the present disclosure. The present inventors prepared a semiconductor wafer W (hereinafter, simply referred to as “wafer”) having a front surface where a single layer of graphene 43 is formed, and irradiated a GCB 44, which is generated from a mixture gas of carbon dioxide gas and helium gas (hereinafter, simply referred to as “mixture gas”), from the GCB irradiation nozzle 13 onto the wafer W. At this time, the graphene 43 was scanned by the GCB 44 in one direction so that a part of the graphene 43 was removed in a band shape as illustrated in FIG. 4. Thereafter, the surface property of the wafer W was analyzed by Raman spectroscopy. FIG. 4 is a partially cut-off view of the wafer W.

In the mixture gas for generating the GCB 44, a flow rate ratio of carbon dioxide gas to helium gas was set to be 1:9. The pressure of the mixture gas in the pressure vessel 26 of the GCB irradiation nozzle 13 was set to be 4 MPa.

FIG. 5 is a partial plan view illustrating a wafer in which graphene is partially removed by the GCB irradiation. FIG. 5 is also a partially cut-off view of the wafer W.

In FIG. 5, the left half of the graphene 43 in the drawing is removed and a base 45, e.g., made of silicon, of the wafer W is exposed. An edge 46 of the graphene 43 is provided at the boundary between the graphene 43 and the exposed base 45.

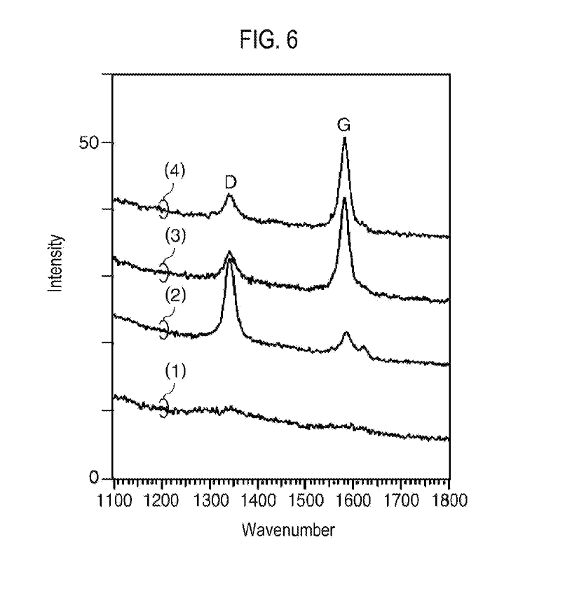

FIG. 6 is a graph illustrating a surface property of the wafer which has a graphene removed portion as illustrated in FIG. 5 wherein the surface property is analyzed by Raman spectroscopy. In FIG. 6, the horizontal axis is a wavenumber (the reciprocal of a wavelength) of a light scattered from the surface of the wafer W, and the vertical axis is the intensity of the scattered light. Reference symbols (1) to (4) in FIG. 6 correspond to positions (1) to (4) in FIG. 5, respectively. The unit of the wavenumber is cm⁻¹ and the unit of the intensity of the scattered light is an arbitrary unit (a.u.).

Ordinarily, light scattered from the graphene has a peak due to vibration in the six-membered ring structure (the hexagonal lattice) of carbon atoms. The peak is called as the G band with a wavenumber near 1590 cm⁻¹. On the other hand, light scattered from armchair edges or from residues or damages of the graphene 43, where a large number of dangling bonds exist, has a peak due to carbon atoms having dangling bonds, which is called the D band with a wavenumber near 1350 cm⁻¹.

As shown in FIGS. 5 and 6, in the position (3), the G band was remarkably generated and the graphene 43 remained without being removed. In the position (2), the G band was hardly produced and the graphene 43 was removed. From these, it can be known that the graphene 43 was cut out to clearly form the edge 46 between the positions (3) and (2). In other words, it can be known that the edge 46 can be clearly formed by irradiating the GCB 44.

Further, from the fact that the G band was hardly generated in the position (2), it can be known that the graphene 43 was removed. Furthermore, from the fact that the D band was remarkably generated, it can be known that the armchair edge was formed as the edge 46 near the position (2).

The present inventors guess the reason why the armchair edge was formed as the edge 46 by irradiating the GCB 44 generated from the mixture gas, as follows. Kinetic energy of gas clusters relates to mass and velocity of the gas clusters. In a case of ionizing gas clusters, the mass of the gas clusters can be measured using the time-of-flight mass spectrometry. In the present embodiment, the mass of the gas clusters was measured by an additional measuring device, which will not be described herein. The velocity of the gas clusters can also be controlled by adjusting a thermal motion speed of the gas clusters, which is a temperature-dependent parameter, and a discharge speed of the gas clusters depending on a pressure of a GCB irradiation nozzle. Accordingly, every gas cluster can be set to have an energy ranging from 0.3 to 0.5 eV, or equal to or higher than 0.5 eV. With regard to the graphene ribbon, the armchair edge is more chemically-stable than the zigzag edge and can maintain the edge shape with lower energy than the zigzag edge. Since the cluster energy of gas molecules (gas molecules of carbon dioxide or helium) of the GCB 44 produced from the mixture gas is low, i.e., about 0.3 to 0.5 eV/cluster, the energy forced to the graphene 43 by the cluster is low. As a result, it is thought that the armchair edge, which needs low-energy for maintaining its shape during machining of the graphene 43, was selectively formed.

Considering the aforementioned reasons, it is also thought that if the cluster energy of the gas molecules of the GCB is slightly higher, e.g., equal to or higher than 0.5 eV/cluster, the zigzag edge, which needs slightly higher energy for maintaining its shape, may be formed.

In addition, from the fact that the G band was not generated in the position (1), it can be known that the graphene 43 was completely removed, and from the fact that the D band was not generated, it can be known that the residue of the graphene 43 did not exist in the position (1). On the other hand, from the fact that the G band is remarkably produced in the position (4), it can be known that the graphene 43 remained without being removed. Moreover, from the fact that the D band was hardly generated in the positions (3) and (4), it can be known that the remaining graphene 43 was not damaged.

The present disclosure is based on the above-described experimental result.

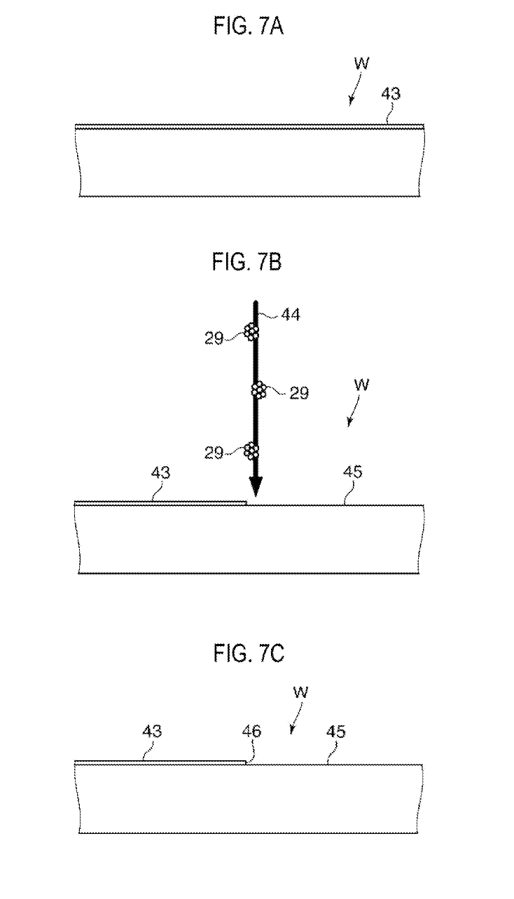

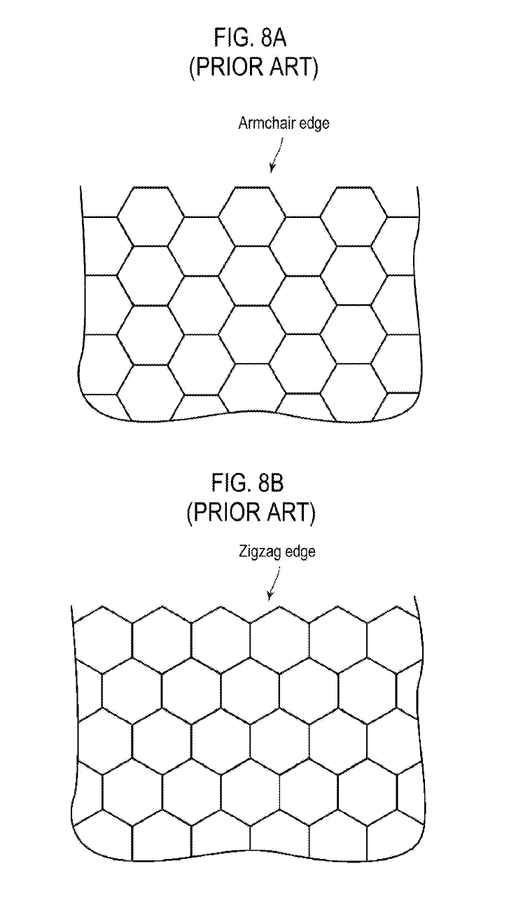

FIGS. 7A to 7C are process diagrams illustrating the graphene machining method according to the present embodiment.

First, a wafer W having a front surface where a single layer of graphene 43 is formed is prepared, and the wafer W is adsorbed on the rotation stage 12 in the GCB irradiation device 10 (see FIG. 7A).

Subsequently, the internal pressure of the chamber 11 is decreased to be, e.g., 10⁻⁴ Pa, and the GCB irradiation nozzle 13 is advanced, by the nozzle moving part 23, over the wafer W adsorbed on the rotation stage 12 so that the GCB irradiation nozzle 13 is arranged to face a desired machining position in the wafer W. Then, the internal pressure of the pressure vessel 26 is set to be 4 MPa, and a plurality of the gas clusters 29 is formed by discharging a predetermined gas from the pressure vessel 26 into the chamber 11. The GCB 44 configured by the gas clusters 29 is irradiated onto the graphene 43 of the wafer W while moving the GCB irradiation nozzle 13 relative to the wafer W (see FIG. 7B).

The GCB 44 removes the graphene 43 in a desired machining position by collision of the gas clusters 29, thereby forming the edge 46 (see FIG. 7C). At this time, the energy of the gas molecule clusters in the GCB 44 is controlled. For example, if the energy of the gas molecule clusters is low, e.g., 0.3 to 0.5 eV/cluster, an armchair edge is formed as the edge 46. If the energy of the gas molecule clusters is slightly high, e.g., equal to or higher than 0.5 eV/cluster, a zigzag edge is formed as the edge 46. The control of the energy of the gas molecule clusters can be performed: by changing an average molecular weight of the gas molecules by changing gas species, changing a combination of gas species in a mixture gas, changing a flow rate ratio of the gas species, or the like; or by changing a gas introduction pressure by changing the internal pressure of the pressure vessel 26 of the GCB irradiation nozzle 13 during a gas discharge.

After the edge 46 is formed by removing the graphene 43 from the desired machining position, and the method according to the present embodiment is completed.

According to the graphene machining method of FIG. 7, the GCB 44 is irradiated onto the graphene 43 in the wafer W. The GCB 44 is a beam of the gas clusters 29 constituted by a plurality of gas molecules or a plurality of gas atoms. However, in the GCB 44, the gas clusters 29 are not ionized and no electric charge is attached thereto. Since the gas clusters 29 of the GCB 44 are much heavier than normal gas molecules or the like, the graphene 43 can be machined into a graphene ribbon by impact at collision. Even though the mass of the gas clusters 29 of the GCB 44 is the same level of the mass of the clusters of the conventional GCIB for example, since no electric charge is attached to the gas clusters 29 of the GCB 44, an effect in which no electric charge remains in the graphene ribbon can be obtained. Moreover, since the kinetic energy of the gas clusters 29 is the main energy of the GCB 44, as the kinetic energy of each gas molecule or the like introduced from the GCB irradiation nozzle 13 increases, the energy of the GCB 44 also increases.

In the present embodiment, by discharging a predetermined gas from the GCB irradiation nozzle 13 to the chamber 11 with a pressure difference larger than atmospheric pressure, the gas is introduced rapidly and the degree of adiabatic expansion of the discharged gas becomes high. From this, the kinetic energy of each gas molecule which forms the gas clusters 29 of the GCB 44 can be increased and the mass of the formed clusters can be further increased. Therefore, the graphene can be certainly machined.

That is to say, similarly to the gas clusters of the GCIB, the kinetic energy of the gas clusters 29 of the GCB 44 can be set to be higher than the kinetic energy of gas molecules or the like that make free motion. As a result, the graphene can be certainly machined. In addition, unlike gas molecule ions or cluster ions of GCIB, no electric charge is attached to the gas molecules of the gas clusters 29 of the GCB 44, whereby it is possible to machine the graphene 43 while preventing electric charges from remaining on the graphene ribbon when irradiating the GCB 44 onto the graphene 43.

Moreover, since the gas clusters 29 of the GCB 44 are not subjected to ion acceleration, the energy of the gas clusters 29 is not unnecessarily increased. Therefore, it is possible to prevent the edge of the graphene 43 from collapsing with which the gas clusters 29 collide. Moreover, the energy of the GCB 44 can be controlled by the gas introduction pressure, gas species or a combination of gas species in the mixture gas, a flow rate ratio of the gas species, or the like. Accordingly, by controlling those parameters, the graphene 43 can be machined while preventing collapse of the edge of the graphene 43, and further the edge shape of the graphene 43 can be controlled.

In the aforementioned method illustrated in FIGS. 7A to 7C, the cluster energy of the gas molecules in the GCB 44 is controlled. In the graphene ribbon, the armchair edge is more chemically-stable than the zigzag edge and can maintain the edge shape with lower energy than the zigzag edge. Therefore, the shape of the edge 46, i.e., the armchair edge or the zigzag edge, of the graphene ribbon obtained by machining using the GCB 44 can be controlled by controlling the cluster energy of the gas molecules of the GCB 44 to thereby control the energy forced on the graphene 43. That is to say, in the aforementioned graphene machining method illustrated in FIG. 7, by irradiating the GCB 44 onto the graphene 43, machining of the graphene 43 and controlling of the shape of the edge 46 can be simultaneously performed.

Moreover, in the aforementioned graphene machining method illustrated in FIG. 7, it is not necessary to ionize the gas molecules. Thus, unlike the conventional etching or GCIB irradiation devices, the GCB irradiation device 10 does not need to have a plasma generation mechanism or electron beam ionization unit, whereby the configuration of the GCB irradiation device 10 can be simplified.

Although the present disclosure has been described with the above embodiment, the present disclosure is not limited to the above embodiment.

For example, in some embodiments, the gas for generating the GCB 44 may be a gas that becomes inactive under room temperature. By doing this, in the machining using the GCB 44, the chemical reaction caused by the gas molecules contained in the gas can be suppressed, whereby it is possible to prevent the six-membered ring structures of carbon in the graphene 43 from being combined with functional groups by the chemical reaction. Moreover, in this case, since a mask film that covers the graphene 43 in order to prevent the remaining graphene 43 from participating in a chemical reaction is unnecessary, it can be suppressed that resist materials forming the mask film form an impurity state in the graphene ribbon. Further, since ashing of the mask film is unnecessary, it is possible to prevent the graphene ribbon from being damaged by excessive ashing.

In addition to the mixture gas of carbon dioxide gas and helium gas used in the aforementioned embodiment, tetrafluoromethane (CF₄) gas, sulfer hexafluoride (SF₆) gas or the like may be used as the gas that becomes inactive under room temperature. Further, tetrafluoromethane gas or sulfer hexafluoride gas may be used as a single gas without being mixed with helium gas.

The present disclosure can be implemented by providing a computer, e.g., the controller 42 of the GCB irradiation device 10, with a storage medium in which software program codes that perform functions of the above-mentioned embodiments are recorded, so that the CPU of the controller 42 reads and executes the program codes recorded in the storage medium.

In this case, the program codes read from the storage medium realize the functions of the above-mentioned embodiment, and the storage medium storing the program codes constitutes the present disclosure.

Any type of storage medium that can store the program codes, such as a RAM, an NVRAM, a floppy disk (registered trademark), a hard disk, a magneto-optical disk, an optical disk (e.g., a CD-ROM, a CD-R, a CD-RW, a DVD (a DVD-ROM, a DVD-RAM, a DVD-RW, or a DVD+RW)), a magnetic tape, a non-volatile memory card, a ROM and so forth, may be used as the storage medium for providing the program codes. Alternatively, the program codes may be provided to the controller 42 through a download from other computers or database (not shown) connected to the Internet, a commercial network, or a local area network.

The functions described in the above-mentioned embodiment can be implemented not only by reading and executing the program codes by the controller 42, but also by allowing an OS (Operating System) running in the CPU to execute all or a part of practical processes based on instructions from the program codes.

The functions described in the aforementioned embodiment can also be implemented by recording the program codes, which are read from the storage medium, on a memory in a function extension board inserted in the controller 42 or a function extension unit connected to the controller 42 and then by allowing a CPU in the function extension board or in the function extension unit to execute all or a part of practical processes based on instructions from the program codes.

The program codes may be in a form of object codes, program codes executed by an interpreter, script data supplied to the OS, or the like.

According to the graphene machining method of the present disclosure, a GCB is irradiated onto graphene. The GCB is a beam constituted by clusters of a plurality of gas molecules or a plurality of gas atoms. However, the clusters in the GCB are not ionized and no electric charge is attached to the clusters. Since the mass of the clusters of the GCB is much heavier than the mass of ordinary gas molecules or the like, the graphene can be machined into a graphene ribbon by impact at collision. Further, since no electric charge is attached to the clusters, it is possible to machine the graphene without remaining electric charges on the graphene ribbon. Moreover, since the clusters in the GCB are not ionized, the clusters are not subjected to ion acceleration, whereby the cluster energy is not unnecessarily increased. Therefore, it is possible to prevent the graphene edge from collapsing with which the gas clusters collide. The energy of the GCB can be controlled by a gas introduction pressure, gas species or a combination of gas species in a mixture gas, a flow rate ratio of the gas species, or the like. By controlling these parameters, the graphene can be machined while preventing the graphene edge from collapsing, and further the edge shape of the graphene can be controlled.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A graphene machining method, comprising:
irradiating a GCB (Gas Cluster Beam) onto graphene.

2. The graphene machining method of claim 1, wherein the graphene is not covered by a mask film.

3. The graphene machining method of claim 1, wherein the GCB is produced from a single or mixture gas that becomes inactive under room temperature.

4. The graphene machining method of claim 3, further comprising:
controlling a cluster energy of gas molecules contained in the irradiated GCB.

5. The graphene machining method of claim 4, wherein the cluster energy of the gas molecules is controlled by at least one of changing gas species forming the single gas or the mixture gas, changing combination of the gas species, or changing a flow rate ratio of the gas species.

6. The graphene machining method of claim 4, the cluster energy of the gas molecules is 0.3 to 0.5 eV/cluster.

7. The graphene machining method of claim 4, wherein the gas molecules includes carbon dioxide gas molecules and helium gas molecules.

8. The graphene machining method of claim 4, the gas molecule includes tetrafluoromethane gas molecules and helium gas molecules.

9. The graphene machining method of claim 4, the gas molecule includes sulfer hexafluoride gas molecules and helium gas molecules.

10. The graphene machining method of claim 4, the cluster energy of the gas molecules is equal to or higher than 0.5 eV/cluster.
